(19) United States
(12) Patent Application Publication
(10) Pub. No.: US 2006/0139039 A1
(43) Pub. Date: Jun. 29, 2006

(54) Systems and methods for a contactless electrical probe

(76) Inventors: David T. Dutton, San Jose, CA (US); Gloria E. Hofler, Sunnyvale, CA (US); Michael James Nystrom, San Jose, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/020,337

(22) Filed: Dec. 23, 2004

(51) Int. Cl. G01R 31/02

(52) U.S. Cl. 324/754

(57) ABSTRACT

There is disclosed a contactless test probe using an ionized gas discharge for making electrical contact with the device under test (DUT). In one embodiment the ionized gas discharge is at or below atmospheric pressure thereby reducing the complexity of the control environment. In one embodiment, the atmospheric gas discharge, i.e. the electrical probing medium, is created and controlled by a micro-hollow cathode. In a further embodiment an extension gate is used to extend/retard the range of the high-density discharge.

### CROSS-REFERENCE TO RELATED APPLICATIONS

The present application is related to concurrently filed, co-pending, and commonly assigned U.S. patent application Ser. No. XX/XXX,XXX, Attorney Docket No. 10041037-1, entitled “NON-CONTACT ELECTRICAL PROBE UTILIZING CHARGED FLUID DROPLETS,” and U.S. patent application Ser. No. XX/XXX,XXX, Attorney Docket No. 10041036-1, entitled “SYSTEM AND METHOD OF TESTING AND UTILIZING A FLUID STREAM,” the disclosures of which are hereby incorporated herein by reference.

### BACKGROUND OF THE INVENTION

There are many applications when it is desired to perform electrical tests on a device without actually making physical contact with the device. For example, organic light emitting diode (OLED) flat panel displays use an emissive flat panel display technology that is an extension of the existing thin film transistor (TFT) liquid crystal display (LCD) technology. While OLED technology is similar to TFT technology, the emissive property of the OLED displays leads to greater complexity, particularly for testing during manufacturing. One difference, as it applies to testing, is that the OLED pixel brightness is controlled with a current signal, as opposed to being controlled with a voltage as are existing LCD displays. This results in the OLED display having one additional transistor per pixel.

To test existing LCD displays, the voltage controlling each pixel can be directly measured even without touching the active area of the display's surface. However, in order to test each pixel of the OLED display, it is necessary to measure current on the display at each pixel also without actually touching the display surface.

While, several techniques are known to sense voltage without actually touching the surface, current sensing without touching presents a problem. For example, voltage can be sensed by using an electron beam to image the surface, such that voltage differences on the surface show as contrast differences. One technique to measure current is to incorporate an additional capacitor per pixel on the OLED display circuit and to measure the charging of this added capacitor through a resistor. This works because the charging rate of the capacitor is a direct inverse function of the resistance value of the resistor. This technique adds complexity to the circuitry and adds a component that will not be used again after testing.

A second technique is to use an electron beam as a contactless probe. This technique requires placing the OLED in a vacuum chamber which is expensive and time consuming.

### BRIEF SUMMARY OF THE INVENTION

There is disclosed a contactless test probe using a plasma plume for making electrical contact with the device under test (DUT). In one embodiment the plasma plume is at or below atmospheric pressure and is created and controlled by a micro-hollow cathode.

In one embodiment, a gas at a pressure in excess of atmospheric pressure is introduced into a test probe and passes through a manifold before being discharged as a plasma plume spanning a gap between the test probe and a DUT. The plasma plume communicates signals across the gap. In a further embodiment the plasma plume can be focused and/or extended.

### BRIEF DESCRIPTION OF THE DRAWINGS

For a more complete understanding of the present invention, reference is now made to the following descriptions taken in conjunction with the accompanying drawing, in which:

FIG. 1 shows one embodiment of a test system utilizing aspects of the disclosure;

FIGS. 2A, 2B and 3 show embodiments of hollow cathodes used for plasma generation;

FIG. 4 shows one embodiment of a hollow cathode having a control grid;

FIG. 5 shows one embodiment of a multi-aperture hollow cathode; and

FIG. 6 shows one embodiment of a process for controlling testing of a DUT.

### DETAILED DESCRIPTION OF THE INVENTION

A contactless test probe can be achieved by using a plasma plume for bridging the gap between the test probe and a device under test (DUT). The plasma plume can be in the form of a mass flow of discharge gas carrying with it ions and electrons. In one embodiment the plasma plume can be created by a micro-hollow cathode discharge.

Micro-hollow cathode discharges are nonequilibrium gas discharges created between a hollow cathode and an anode. The anode can be solid or hollow as desired. The physics of micro-hollow cathode discharge are known and such devices are being used for many different applications, such as, for example, lighting, displays, chemical sensors, photosensors, excimer radiation sources and arc discharge lamp ignition sources. One source of information about the construction and use of micro-hollow cathode discharge devices is Sung-Jin Park et al., IEEE Journal on Selected Topics in Quantum Electronics Vol. 8, No. 1, January/February 2002, hereby incorporated by reference herein.

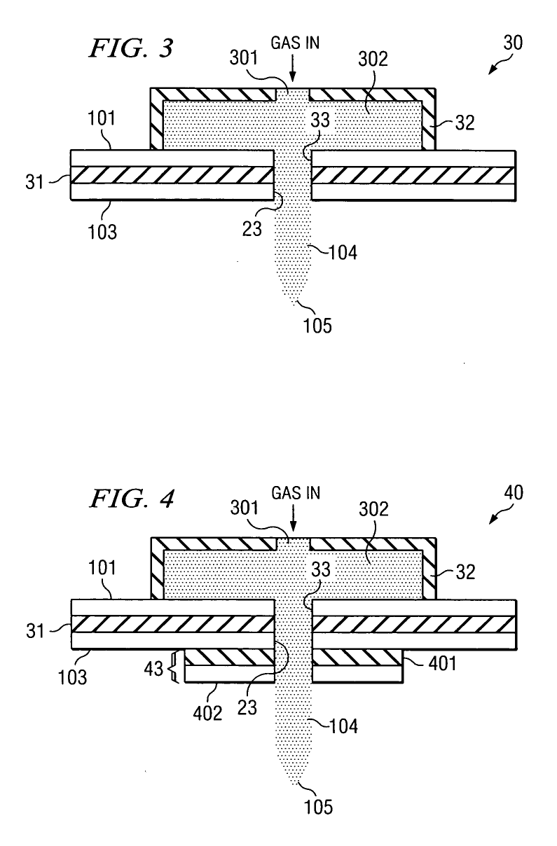

The micro-hollow device contemplated herein has a diameter of 0.02 mm to 0.2 mm diameter with a plasma plume extending approximately 0.1 mm to several millimeters. The input gas, for example, is argon at a typical input pressure of 48 kpascal to 100 kPascal. The plasma generation materials within the device (for example, in FIG. 3, the material of elements 101, 31 and 103, respectively) are, for example, metal/dielectric/metal, metal/polymer/metal, or metal/semiconductor/metal. Exemplary metals are Au, Ti, or Cu, but could be any number of other metals. Exemplary dielectrics are sapphire or ceramic, and an exemplary semiconductor is Si. Exemplary polymers could be, for example, Kapton™ or RT Duriod (PTFE).

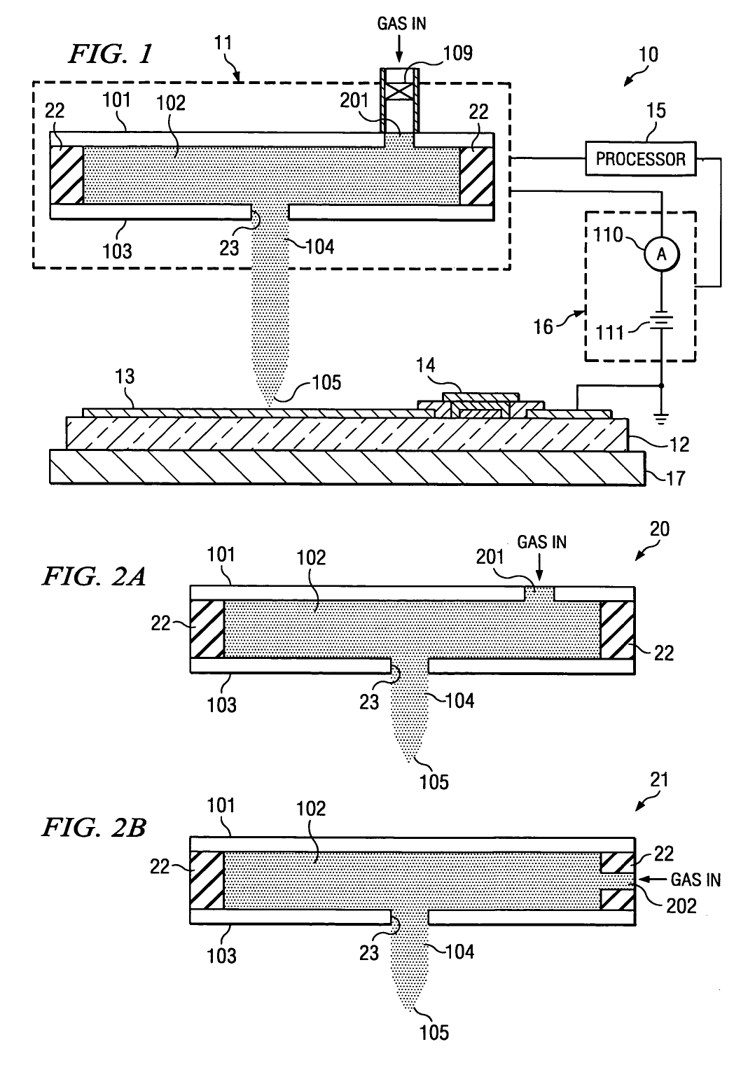

As shown in FIG. 1, a gas at above atmospheric pressure enters probe 11 via opening 201 which opening is shown off-set from exit aperture 23 and having, optionally, flow valve 109 therein. The gas is contained in manifold 102 and exits via aperture 23 of micro-hollow cathode 103 to an open environment at or below atmospheric pressure. Plasma plume 104 carries the ions and electrons a distance determined by the gas flow rate and the lifetime of the ions and electrons. The plasma plume also contains radicals which are an electrically neutral species that do not contribute to current flow. However, the initial ion and electron density, the lifetime of each species, and the rate of flow of the carrier gas all combined to determine the extension of the plasma plume. As set forth above, in one embodiment this extension distance is approximately 0.1 mm and can extend to several millimeters. Plume tip 105 of plasma plume 104 is adjusted so that it touches (or comes in close proximity to) contact 13 of DUT 12. Adjustment can be made by movement of head 11 or, as will be discussed, by changing the length of plasma plume 104.

In the example shown in FIG. 1, test probe 11 is used to electrically connect cathode 103 to a conductive object (contact 13) in the path of the plasma plume in order to electrically probe DUT 12 for current or voltage without a solid probe coming into contact with the device surface.

Plasma plume 104 completes an electrical path from contact 13, transistor 14, voltage source 111, and through meter 110 (or any other sensor) to probe 11 thereby allowing for the measurement of current flow through transistor 14 of TFT drive circuit for OLED panel 12. A processor, such as processor 15, controls both the application of the current as well as the generation of the plasma such that the plasma and the signals (if any) carried thereby can be selectively controlled, if desired. Note that processor 15 can be part of controller 16 or could be separate therefrom, or could be part of test probe 11, if desired.

When the test of display panel 12 is complete, the plasma can be stopped (by reducing the gas flow into manifold 102, by electronic circuitry, or by a valve, such as valve 109), the panel to be tested is removed, and another panel inserted in its place. Note that in this embodiment, it is contemplated that test probe 11 and test bed 17, as well as the circuitry that controls the test fixture are parts of a permanent test system. Alternatively, the test probe can be hand held as part of a portable device or the test probe could be part of an (x-y) scanning head, if desired. In any event, plasma can be sent from the test probe to the DUT to complete an electrical circuit for the purpose of measuring current flow (or other signals) between the DUT and test probe 11. It is contemplated that the distance of the gap between test probe 11 and the surface of the DUT would be approximately 0.1 mm, which at present is the minimum allowed spacing to accommodate for non-planarities of the test head and the DUT.

While ion and electron generation can be accomplished in various ways, the embodiment illustrated uses a micro-hollow aperture in cathode 103 to produce ions, electrons and neutral species. The strike voltage necessary to create the plasma from the gas depends upon the dielectric, for example, dielectric 31 (FIG. 3), and the thickness thereof. In one embodiment, for example the embodiment shown in FIG. 3, the strike voltage would be in the range of 500-700 volts applied between cathode 103 and anode 101. Once the plasma has started, the sustaining voltage will depend upon the dimensions of the device and particularly the spacing between the anode and cathode. In an exemplary embodiment, the sustaining voltage would be in the range of 200-300 volts.

FIG. 2A shows one embodiment where above-atmospheric manifold 102 accepts gas via input 201 as discussed above with respect to test probe 11. In test probe 20 the plasma is generated in manifold 102 between anode 102 and cathode 103. In this configuration, cathode 103 is the lower containing wall and anode 101 is the upper containing wall. Lower, in this illustration, means closer to the DUT while upper means further away from the DUT. Insulating sidewalls 22 provide a complete enclosure for the gas in manifold 102. The internal diameter of the manifold can be reduced to the diameter of exit aperture 23 to reduce turbulence as the ionized gas exits the aperture. In effect, then, the manifold would be a tube.

FIG. 2B shows probe 21 where the gas above atmospheric pressure enters side orifice 202 instead of top orifice 201 as shown in FIG. 2A. After the strike voltage has been applied, a low-density plasma will exist inside manifold probe 20 or 21, with a high-density plasma discharge generated at the micro-hollow cathode aperture 23 due to the oscillatory motion of electrons and photon reflection at the aperture.

FIG. 3 shows an alternative embodiment where anode 101 and cathode 103 are separated by dielectric 31. Manifold 302 sits on top of anode 101 and is defined by insulating material 32. In this embodiment, gas enters via orifice 301 and enters micro-hollow cathode 23 via orifice 33. A high-density discharge is produced at the cathode aperture. In this configuration, very little, if any, plasma is generated within manifold 302. Also, in this configuration the anode and cathode metal layers can be interchanged since their geometries are symmetrical and both layers appear at exit aperture 33 so as to control the creation of the plasma. This embodiment also facilitates reducing the manifold diameter to the diameter of the exit aperture to improve gas flow and to reduce turbulence. Reduction of turbulence is important and, while not shown, a capillary structure, such as a tube, would achieve this goal, and the manifold structure leading to the micro-hollow cathode can be adjusted to reduce turbulence at orifice 33 as well as at orifice 23. In one embodiment, the depth of the orifice is ten times the diameter of the capillary created by the manifold/orifice structure.

While the embodiments show the cathode and anode to be essentially parallel to each other, any arrangement will work so long as plasma is generated. One such arrangement would be to construct the cathode as a tube with the anode running down the center of the tube. The plasma is then created in the tube.

FIG. 4 shows an embodiment of the probe using gate 43 operating in conjunction with cathode 103 to control the extension of plasma plume 104. Gate 43, which in the embodiment shown in FIG. 4, creates an electrostatic field defined by dielectric 401 and cathode (or anode) 402. Gate 43 is selectively controlled, for example, by processor 15, FIG. 1. Gate 43 can be used to modify the distance the plasma plume extends from the orifice of the probe. In this manner, the test probe need not be maintained at a prefixed distance from the DUT and the plume extension can be selectively adjusted as desired. For example, such an arrangement could enable a hand-held plasma probe where the plasma plume is extended or retracted as needed to contact the DUT. Such extension/retraction can also be accomplished by changing the carrier gas pressure, for example, by adjustment, (manually or electrically) of valve 109 (FIG. 1).

Note that while a positive extension of the plasma plume has been shown, a retraction of the plume can also be achieved. Since both electrons and ions are transported via mass flow (ambipolar), the electrons could be repelled, for example, by gate 43 to focus the ions, or vice-versa, so as to achieve a unipolar plume. The low mass electrons (and perhaps the higher mass ions) could be repelled enough for them to move in reverse towards the exit aperture, against the gas flow thereby reducing the length of the plume (retraction). Also, if desired, additional ions or other artifacts can be introduced into the plasma stream after it emerges from cathode 103. These additional features can be used for additional testing or to perform additional functions on the DUT. Gate 43 can be used to close down one or more apertures in the cathode to allow for selective positioning of the plasma plume. This facilitates testing of multiple DUTs concurrently or testing of multiple elements of a single DUT.

Gate 43 can be structured by splitting the orifice to steer and/or focus the plasma plume as desired. Also, gate 43 can be structured to effectively prevent electrical flow across the gap between the test head and the DUT by reducing the plume so it moves away from the DUT, or alternatively, by reducing the electron flow within the plume.

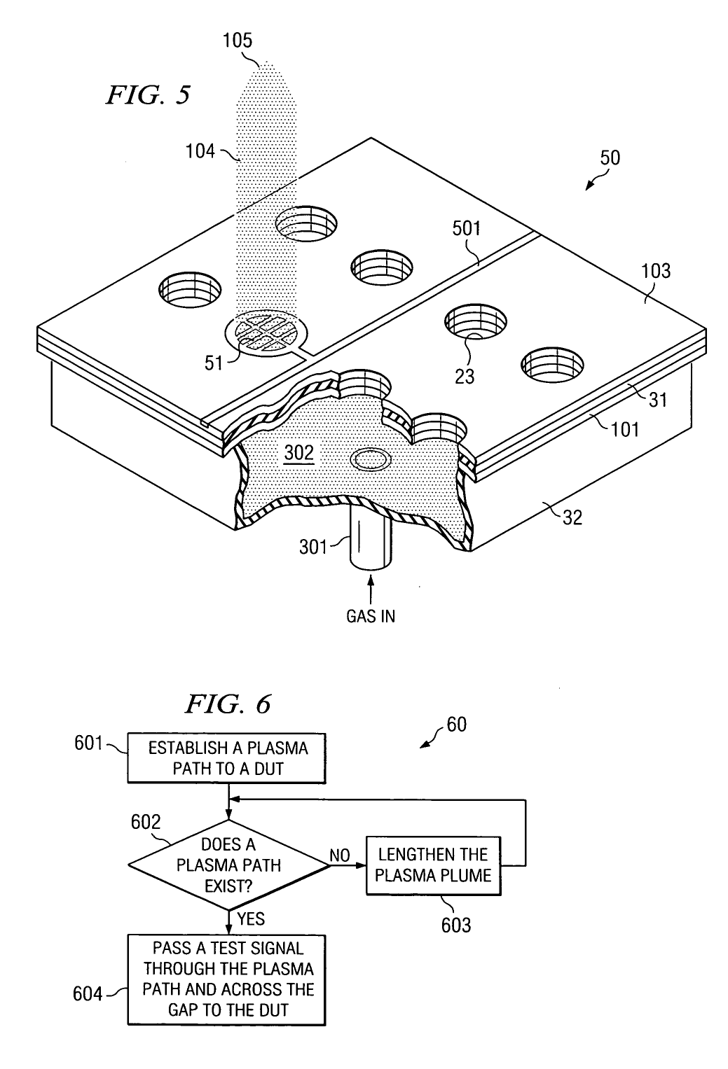

FIG. 5 shows one embodiment of an array of apertures 23 with gate 51 controlling the plasma extension of an individual orifice. Gate 51 can be constructed similar to gate 43 (FIG. 4). Lead 501 provides control signals to gate 51. Gates can be located at all the orifices, if desired, and they can be selectively controlled by one or more leads 501. Note that a dielectric layer, while not shown, is typically located between gates 51 and cathode 103. The orifices are aligned with a different element of a DUT and tests, or test patterns, performed on one or more of the elements at one time or in sequence. By constructing test probe 50 with multiple manifolds, independent tests can be conducted on different DUTs, or on different test points of the same DUT.

Note also that while the disclosure has been framed in context to testing an OLED panel, the concepts discussed herein can be used to test any device without actually touching that device.

Also note that while the probe discussed herein is used in a simple current or voltage measurement arrangement, many different types of signals can be carried by the plasma plume and thus complex testing can be performed using the concepts discussed herein. In addition, signals in the RF spectrum can be carried as well as digital signals, if desired. The plasma discharge may be tailored to facilitate transmittal of signals in different frequency ranges. The flow rate of the carrier gas, for example by regulating flow valve 109 (FIG. 1), can be used to produce certain resonances with different electrical frequencies which can be used, if desired, for testing purposes.

FIG. 6 shows one embodiment 60 of a method for testing a DUT. Process 601 establishes a plasma path to the DUT. This can be done by placing the DUT on a test fixture, or by bringing the test probe into the vicinity of the DUT. In some situations, this requires controlling the input gas flow or controlling the generation of ions and electrons by changes in voltage at the anode, the cathode, or both, or by using a gate, such as gate 43, FIG. 4.

Process 602 determines if a plasma path exists to the DUT. If it does not, then process 603 extends the length of the plasma plume, as discussed above, under control of valve 109 (FIG. 1), or gate 43 (FIG. 4), or both.

Once the plasma path exists then process 604 passes a test signal across the physical gap between the test probe and the DUT.

Although the present invention and its advantages have been described in detail, it should be understood that various changes, substitutions and alterations can be made herein without departing from the invention as defined by the appended claims.

What is claimed is:

1. A probe comprising:
an orifice separated from a DUT by a gap; and
a source of plasma for spanning said gap to said DUT.

2. The probe of claim 1 wherein said plasma communicates signals from said orifice to said DUT.

3. The probe of claim 1 wherein said plasma source is a micro-hollow cathode discharge.

4. The probe of claim 3 wherein said micro-hollow cathode discharge creates a plasma plume having a mass flow of discharge gas carrying ions, electrons, and neutral species.

5. The probe of claim 4 wherein said plasma plume is at a pressure at or below atmospheric pressure.

6. The probe of claim 4 wherein the length of said plasma plume is determined by the flow rate of said discharge gas and the lifetime of said ions.

7. The probe of claim 4 wherein said probe further comprises:
means for controlling the extension of said plasma plume.

8. The probe of claim 3 wherein said plasma plume is unbounded by physical structure between said orifice and said DUT.

9. The probe of claim 4 further comprising:
means for controlling the length of said plasma plume.

10. The probe of claim 1 further comprising:
means for controlling a length of plasma from said orifice to said DUT.

11. The probe of claim 1 further comprising:
a manifold for holding gas, and wherein said plasma source comprises:
an anode and a cathode for converting gas held in said manifold to said plasma.

12. The probe of claim 10 wherein at least a portion of said manifold has a diameter essentially the same as the diameter of said orifice.

13. A method of testing a DUT, said method comprising:
generating a plasma plume extending to said DUT; and
passing a test signal through said plasma plume to said DUT.

14. The method of claim 13 wherein said plasma plume is generated at or below atmospheric pressure.

15. The method of claim 13 wherein said plasma plume is unbounded by physical structure.

16. The method of claim 13 wherein said DUT is part of an organic light emitting diode display.

17. The method of claim 13 wherein said generating comprises:
selectively extending said plasma plume.

18. The method of claim 13 wherein said generating comprises:
introducing artifacts into said plasma plume.

19. A test device comprising:
means for providing test signals; and
means spaced apart from a DUT for generating a plasma plume for providing an electrical path to said DUT for the passage of provided test signals.

20. The test device of claim 19 further comprising:
selectively controlling said plasma plume.

21. The test device of claim 19 further comprising:
means for controlling test procedures between said test signal providing means and said DUT.

22. A test probe comprising:
an input for receiving gas under pressure;
a plasma source; and
a hollow cathode through which portions of said pressurized gas can escape into atmospheric pressure as a mass flow of discharge gas carrying electrons and ions, said discharge gas operable for carrying test signals from said probe to a DUT without said probe touching said DUT.

23. The probe of claim 22 further comprising:
at least one chamber for holding received gas under pressure.

24. The probe of claim 22 further comprising:
at least one aperture in the surface of said hollow cathode through which aperture said pressurized gas escapes.
